(19) United States
(12) Patent Application Publication
(10) Pub. No.: US 2024/0192600 A1
(43) Pub. Date: Jun. 13, 2024

(54) MANUFACTURING METHOD OF METAL MASK AND METAL MASK THEREOF

(71) Applicant: DARWIN PRECISIONS CORPORATION, Hsinchu County (TW)

(72) Inventors: Cheng-Wei Lin, Hsinchu County (TW); Chi-Wei Lin, Hsinchu County (TW)

(21) Appl. No.: 18/198,854

(22) Filed: May 18, 2023

(30) Foreign Application Priority Data
Dec. 7, 2022 (TW) 111147016

(51) Int. Cl. G03F 7/09; G03F 1/50; G03F 1/80; G03F 1/82; G03F 7/36

(52) U.S. Cl. CPC G03F 7/094; G03F 1/50; G03F 1/80; G03F 1/82; G03F 7/36

(57) ABSTRACT

A manufacturing method of a metal mask comprises: providing a metal plate having a first surface and a second surface opposite to each other, and the first surface has preset opening regions; forming a first photoresist layer on the first surface which has first apertures corresponding to the preset opening regions respectively, and each preset opening region is partially exposed to each first aperture, and an area of the first aperture is 75%-100% of an area of the preset opening region; forming a second photoresist layer on the second surface which has second apertures, and the second surface is exposed to the second apertures; forming first etching parts on the first surface and corresponding to the first apertures respectively, and each first etching part has a first opening located in each preset opening region; forming second etching parts on the second surface and corresponding to the second apertures respectively.

### FIELD OF THE INVENTION

The present invention relates to a manufacturing method of a metal mask, and in particular to a manufacturing method of a metal mask that can be used for evaporation, and the manufactured metal mask.

### BACKGROUND OF THE INVENTION

Fine Metal Mask (FMM) is commonly used in the display industry, for example, in the manufacture of display panels, for evaporating pixel materials onto a substrate to form pixel arrays. The fine metal mask has a plurality of openings corresponding to positions where the pixel arrays will be formed on the substrate in the evaporation process. At present, FMM manufactured by the process of chemical etching have problems of such as lack of opening uniformity, deviation from designed shape, etc. Such poor FMM will affect pixel accuracy when it is used to perform the pixel evaporation, and results in problems such as lack of pattern accuracy and color mixing.

### SUMMARY OF THE INVENTION

The present invention provides a manufacturing method of a metal mask, which can improve the opening yield rate and uniformity of the opening of the metal mask.

The present invention also provides a metal mask, which has better opening yield rate and better uniformity of the opening.

The manufacturing method of the metal mask provided by the present invention comprises the following steps: providing a metal plate having a first surface and a second surface opposite to each other, wherein the first surface has a plurality of preset opening regions, and each of the preset opening regions has a first area; forming a first photoresist layer on the first surface of the metal plate, wherein the first photoresist layer has a plurality of first apertures, and each of the first apertures has a second area; the plurality of first apertures correspond to the plurality of preset opening regions respectively, and each of the preset opening regions is partially exposed to each of the first apertures, wherein the second area is 75%-100% of the first area; forming a second photoresist layer on the second surface of the metal plate, wherein the second photoresist layer has a plurality of second apertures, and the second surface is exposed to the plurality of second apertures; forming a plurality of first etching parts on the first surface, wherein the plurality of first etching parts correspond to the plurality of first apertures respectively; each of the first etching parts has a first opening, and each of the first openings is located in each of the preset opening regions; forming a plurality of second etching parts on the second surface, wherein the plurality of second etching parts correspond to the plurality of second apertures respectively.

In an embodiment of the present invention, the manufacturing method of the metal mask described above further comprises performing a first etching and a second etching. The first etching comprises forming the plurality of first etching parts on the first surface and forming the plurality of second etching parts on the second surface. The second etching comprises: forming a protective layer on the metal plate, and the protective layer covers the second photoresist layer and fills the plurality of second etching parts; performing further etching on the plurality of first etching parts, and allowing each of the first etching parts to be communicated with each of the second etching parts to form a plurality of evaporation holes.

In an embodiment of the present invention, the manufacturing method of the metal mask described above further comprises removing the first photoresist layer, the second photoresist layer, and the protective layer.

In an embodiment of the present invention, each of the evaporation holes described above has a third area, the third area is smaller than the second area, and each of the evaporation holes forms an evaporation angle relative to each of the first openings.

In an embodiment of the present invention, the evaporation angle described above is an included angle formed between a connecting line and the first surface; the connecting line connects a hole edge of each of the evaporation holes and an edge of the first opening.

In an embodiment of the present invention, each of the evaporation holes described above further has a first hole edge, and each of the first openings further has a first edge corresponding to the first hole edge; the evaporation angle further includes a first evaporation angle, and the first evaporation angle is formed between a connecting line and the first surface; the connecting line connects a midpoint of each of the first hole edges and a midpoint of each of the first edges.

In an embodiment of the present invention, each of the evaporation holes described above has a second hole edge, and each of the second hole edges is adjacent to each of the first hole edges and forms a first intersection; the evaporation angle further includes a second evaporation angle, and the second evaporation angle is formed between a connecting line and the first surface; the connecting line connects the first intersection and the first edge.

In an embodiment of the present invention, a difference between the first evaporation angle and the second evaporation angle described above is less than 5 degrees.

In an embodiment of the present invention, each of the first apertures described above has a first side; the step of forming the first photoresist layer further comprises forming the plurality of first apertures, and the first side of each of the first apertures has a curve design.

In an embodiment of the present invention, the first side described above has an arc curve inwardly concaved towards each of the first apertures.

In an embodiment of the present invention, each of the first openings described above further has a first edge corresponding to the first side, and the step of forming the plurality of first etching parts further comprises allowing a photoresist of the first photoresist layer to extend out of the first edge and cover a part of the first etching part.

In an embodiment of the present invention, each of the first openings described above is a geometric figure and has a plurality of edges, each of the first apertures has a plurality of sides, and the plurality of sides correspond to the plurality of edges respectively; the step of forming the first photoresist layer described above further comprises forming the plurality of first apertures, and the plurality of sides of each of the first apertures respectively have a curve design.

The present invention also provides a metal mask which comprises a metal body, a first etching part, a second etching part, and an evaporation hole. The metal body has a first surface and a second surface; the first etching part has a first opening located on the first surface; the second etching part has a second opening located on the second surface, and the second opening is smaller than the first opening; the evaporation hole is located between the first etching part and the second etching part, and the first etching part and the second etching part are communicated with each other at the evaporation hole. The evaporation hole forms a first evaporation angle and a second evaporation angle relative to the first opening, and a difference between the first evaporation angle and the second evaporation angle is less than 5 degrees.

The present invention also provides a metal mask prepared by the manufacturing method of the metal mask described above.

In the present invention, the first photoresist layer is adopted, each of the preset opening regions on the first surface of the metal plate is partially exposed to each of the first apertures, and the area of the first aperture can be smaller than that of the preset opening region, so that the deviation caused by the flow of etching liquid can be compensated, and the error of the first opening relative to the preset opening region is smaller or zero, and the design objectives regarding the first opening and the evaporation angle thereof are achieved. The metal mask provided by the present invention has better first opening yield rate and better uniformity of the first opening, and is beneficial to improving abnormal situations of evaporation.

In order to make the aforementioned and other objects, features and advantages of the present invention more obvious and comprehensible, embodiments accompanied with figures are described in detail below.

### BRIEF DESCRIPTION OF THE DRAWINGS

FIG. 1 is a flow diagram of a manufacturing method of a metal mask according to an embodiment of the present invention.

FIG. 2 is a schematic diagram of a preset opening region of a metal mask according to an embodiment of the present invention.

FIG. 3 is a schematic operation diagram of a manufacturing method of a metal mask according to an embodiment of the present invention.

FIG. 4 is a bottom view of FIG. 3.

FIG. 5 is another schematic operation diagram of a manufacturing method of a metal mask according to an embodiment of the present invention.

FIG. 6 is a partial bottom view of FIG. 5.

FIG. 7 is another partial bottom view of FIG. 5.

FIG. 8 is a schematic sectional view of a metal mask according to an embodiment of the present invention.

FIG. 9 is a partial bottom view of a metal mask according to an embodiment of the present invention.

FIG. 10 is a partial bottom view of a metal mask according to another embodiment of the present invention.

FIG. 11 is a partial image diagram of a metal mask according to an embodiment of the present invention.

FIG. 12 is a schematic operation diagram of a manufacturing method of a metal mask according to other embodiments of the present invention.

FIG. 13 is a schematic diagram of a relationship between design compensation and an opening area according to an embodiment of the present invention.

### DETAILED DESCRIPTION OF PREFERRED EMBODIMENTS

The foregoing and other technical contents and other features and advantages of the present invention will be clearly presented from the following detailed description of a preferred embodiment in cooperation with the accompanying drawings. Directional terms mentioned in the following examples, for example, upper, lower, left, right, front, back, top or bottom, are only used to describe directions referring to the attached drawings. Therefore, the directional terms used are for illustration and not for limitation.

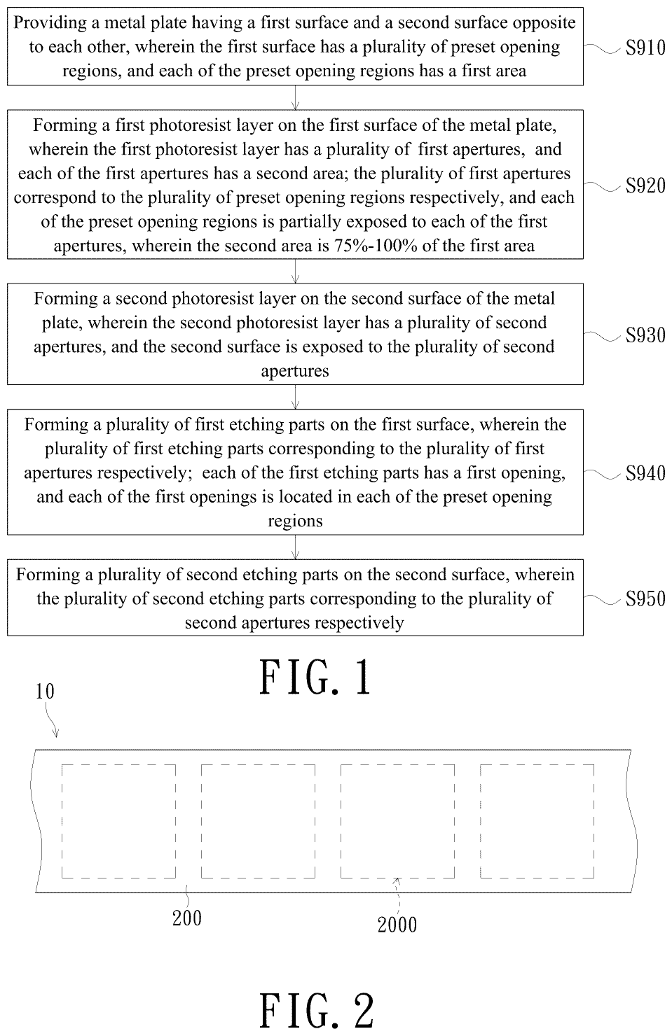

The embodiment of the present invention provides a method for manufacturing a metal mask by chemical etching through a photoresist pattern. FIG. 1 is a flow diagram of a manufacturing method of a metal mask according to an embodiment of the present invention. As shown in FIG. 1, the manufacturing method of the metal mask comprises steps S910-S950. Step S910 comprises: providing a metal plate having a first surface and a second surface opposite to each other, wherein the first surface has a plurality of preset opening regions, and each of the preset opening regions has a first area. Step S920 comprises: forming a first photoresist layer on the first surface of the metal plate, wherein the first photoresist layer has a plurality of first apertures, and each of the first apertures has a second area; the plurality of first apertures correspond to the plurality of preset opening regions respectively, and each of the preset opening regions is partially exposed to each of the first apertures, wherein the second area is 75%-100% of the first area. Step S930 comprises: forming a second photoresist layer on the second surface of the metal plate, wherein the second photoresist layer has a plurality of second apertures, and the second surface is exposed to the plurality of second apertures. Step S940 comprises: forming a plurality of first etching parts on the first surface, wherein the plurality of first etching parts correspond to the plurality of first apertures respectively; each of the first etching parts has a first opening, and each of the first openings is located in each of the preset opening regions. Step S950 comprises forming a plurality of second etching parts on the second surface, wherein the plurality of second etching parts correspond to the plurality of second apertures respectively. Steps S910-S950 are further described below.

The metal plate provided in step S910 can be pretreated in any known way, so as to be suitable for steps S920-S950. Referring to the schematic operation diagram shown in FIG. 2, the metal plate 10 has a plurality of preset opening regions 2000 on the first surface 200. A plurality of first openings 230 (described later) are to be formed in the plurality of preset opening regions 2000. Based on a design of evaporation holes of the metal mask, as shown in FIG. 2, a plurality of preset opening regions 2000 can be distributed at a certain interval in a transverse direction, but not limited thereto. For example, in other embodiments, the metal plate 10 has a plurality of preset opening regions 2000 arranged in a longitudinal direction and a transverse direction.

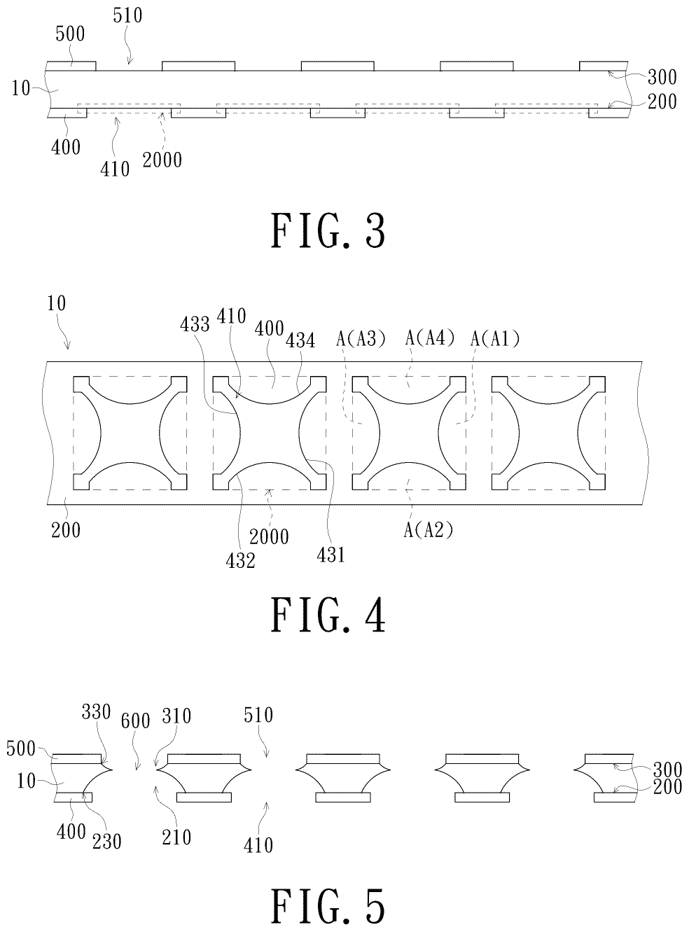

Step S920 further comprises a step of coating a photoresist on the first surface 200, and exposing and developing. Step S930 further comprises a step of coating a photoresist on the second surface 300, and exposing and developing. The photoresists used in the first surface 200 and the second surface 300 can be the same, for example, they are both positive photoresists. The first surface 200 and the second surface 300 can be exposed differently, for example, different photomasks are employed to form different photoresist patterns. Steps S920 and S930 can be performed at the same time or at different times, and step S930 may be performed before step S920. The schematic operation diagram of FIG. 3 illustrates a state after the completion of steps S920 and S930. As shown in FIG. 3, the photoresist on the first surface 200 is exposed and developed to form a first photoresist layer 400, in which a plurality of first apertures 410 are formed corresponding to a plurality of preset opening regions 2000, and each preset opening region 2000 is partially exposed to each first aperture 410. That is, the first aperture 410 and the preset opening region 2000 should be different in size or in shape. In the preferred embodiment of the present invention, the shape of the first aperture 410 is different from that of the preset opening region 2000. On the other hand, the photoresist on the second surface 300 is exposed and developed to form a second photoresist layer 500, in which a plurality of second apertures 510 are formed. The second surface 300 is exposed to the plurality of second apertures 510, and a plurality of second openings 330 (described later) are to be formed from the exposed portion.

Further referring to FIG. 4, which is a bottom view of FIG. 3, the size of the first aperture 410 is different from that of the preset opening region 2000, and the preset opening region 2000 is therefore partially exposed. Further, the shape of the first aperture 410 is also different from that of the preset opening region 2000. In an embodiment of the present invention, the preset opening region 2000 is rectangular. As shown in FIG. 4, the first aperture 410 has four sides, which correspond to four edges of the preset opening region 2000 respectively, and has a first side 431 on one side. The first side 431 has a curve design. The first aperture 410 can further have a second side 432, a third side 433, and a fourth side 434, and all the four sides can respectively have a curve design. Positions where the curves are designed on the sides can be, for example, on the majority of middle sections of the sides.

The curve design of the first side 431 can be, for example, an arc curve inwardly concaved towards the first aperture 410. Depending on a design of the metal mask 1, the arc curve can have various angles. For example, a curve of an arc with a larger angle can make the side inwardly concaved more and the first aperture 410 smaller, while a curve of an arc with a smaller angle can make the side inwardly concaved less and the first aperture 410 larger. Based on a design of the inwardly concaved curve of the side, regions A are formed between the curves and the preset opening regions 2000. In the embodiment of the present invention, the regions A can comprise, for example, regions A1-A4, which are composed of the curves and four edges of the preset opening regions 2000 respectively. In the embodiment of the present invention, a total area of the regions A accounts for 0%-25% of an area of the preset opening region 2000, and is preferably greater than 0% and not more than 20%. If each preset opening region 2000 has a first area S1 and each first aperture 410 has a second area S2, the second area S2 is 75%-100% of the first area S1. Based on the inwardly concaved curve design of the first aperture 410 on the sides, the embodiment of the present invention is beneficial to compensating metal material reduction in an etching step (described later), such as the metal material reduced in the first surface 200, so that an error of the first opening 230 relative to the preset opening region 2000 is smaller or zero, such as being greater than 70% and less than 120%, and preferably close to 100% of the preset opening region 2000.

Steps S940 and S950 further comprise performing a first etching to allow an etching liquid to etch the first surface 200 and the second surface 300 of the metal plate 10 from the exposed portions thereof. Steps S940 and S950 may be performed at the same time or at different times. In the embodiment of the present invention, the first etching may preliminarily complete a first etching part 210 and a second etching part 310. Steps S940 and S950 can further comprise performing a second etching to allow the etching liquid to further etch in the first etching part 210. The second etching can comprise forming a protective layer (not shown) on the second photoresist layer 500. Preferably, the protective layer fills the plurality of second etching parts 310. In the embodiment of the present invention, the protective layer can keep a shape of the second etching part 310 during the second etching. The second etching can allow the first etching part 210 and the second etching part 310 to be communicated to form an evaporation hole 600.

The schematic operation diagram of FIG. 5 illustrates a state after the completion of steps S940 and S950. As shown in FIG. 5, steps S940 and S950 form the plurality of first etching parts 210 from the first surface 200 and the plurality of second etching parts 310 from the second surface 300. The plurality of first etching parts 210 correspond to the plurality of first apertures 410 respectively, and each of the first etching parts 210 has the first opening 230 located on the first surface 200. The plurality of second etching parts 310 correspond to the plurality of second apertures 510 respectively, and each of the second etching parts 310 has the second opening 330 located on the second surface 300. In the embodiment of the present invention, each of the first openings 230 can be located approximately in each of the preset opening regions 2000. For example, when the preset opening region 2000 is rectangular, the first opening 230 is substantially rectangular. Each of the first openings 230 can have a third area S3.

In step S940, the etching liquid flows in the first etching part 210. Generally speaking, the flow of the etching liquid may be non-directional flow, which can cause a deviation of the first opening 230 from a design target. However, in the embodiment of the present invention, because of the pattern design of the first photoresist layer 400, wherein the sides of the first aperture 410 have inwardly concaved curve design and the regions A (for example, A1-A4) are formed, the deviation caused by the flow of the etching liquid can be compensated.

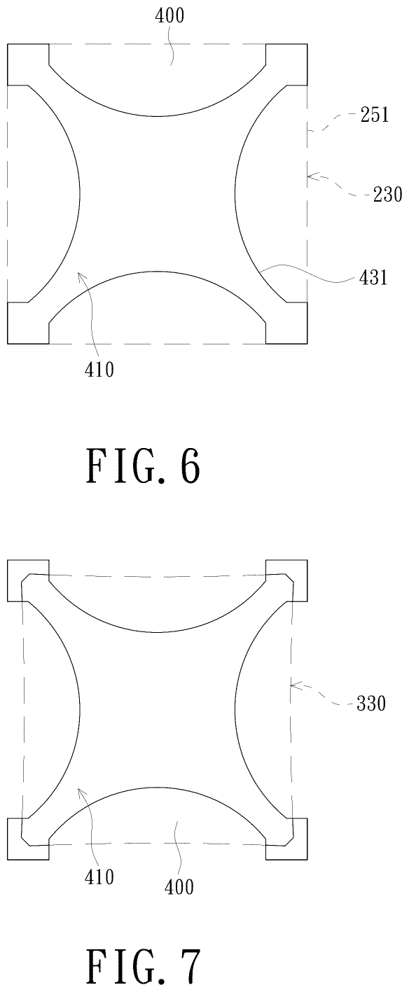

Further referring to FIGS. 6 to 7, which are respectively partial bottom views of FIG. 5, FIG. 6 illustrates a relationship between the first photoresist layer 400 and the first opening 230, and FIG. 7 illustrates a relationship between the first photoresist layer 400 and the second opening 330. The first opening 230 can be a geometric figure. In an embodiment of the present invention, the first opening 230 is substantially rectangular. As shown in FIG. 6, the first opening 230 substantially has four edges which comprise a first edge 251 corresponding to the first side 431 of the first aperture 410. In the embodiment of the present invention, step S940 can further comprise allowing the photoresist of the first photoresist layer 400 to extend out of the first edge 251 and cover a part of the first etching part 210. That is, even if the side of the first aperture 410 has an inwardly concaved curve design based on the pattern design of the first photoresist layer 400, it does not mean that an edge of the first opening 230 also has the same inwardly concaved curve. In some embodiments of the present invention, the first opening 230 can have other geometric shapes than a rectangle. According to the present invention, the first aperture 410 and/or the total area of the regions A can be designed according to a shape of the first opening 230, a number of the edges and other conditions. For example, the first aperture 410 may have a plurality of sides corresponding to or roughly corresponding to a plurality of edges, and some or all of the sides can further have the curve designs. The curve design of each side can be the same or different.

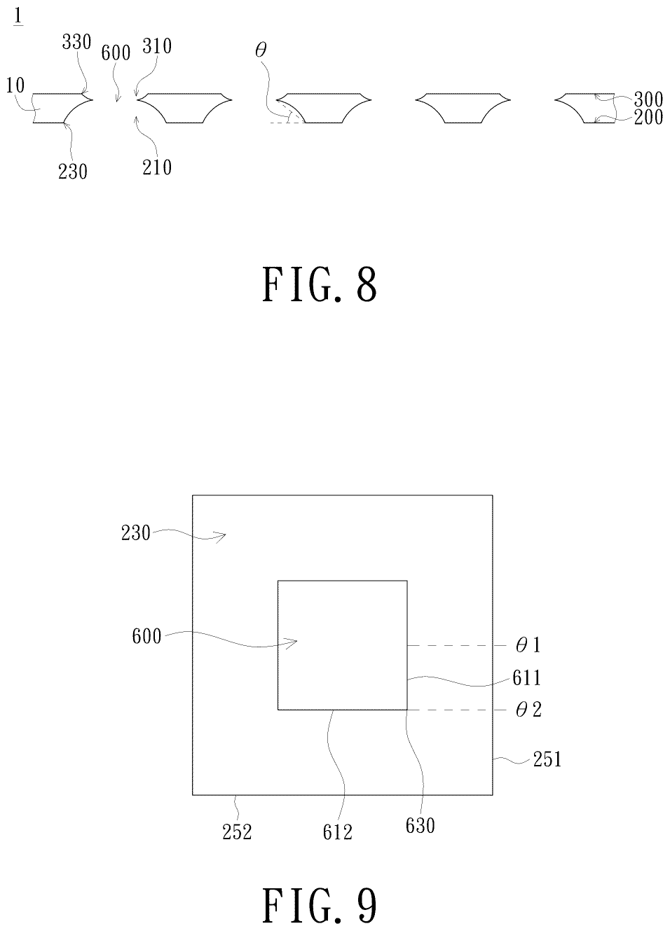

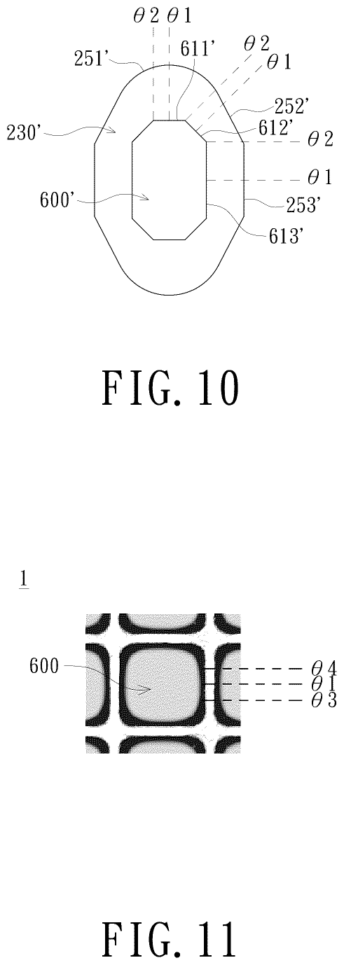

An embodiment of the manufacturing method of the present invention can further comprise a step of removing the first photoresist layer 400, the second photoresist layer 500, and the protective layer. The removal method can be carried out in any known way, which is not detailed here. After the removal, the metal mask 1 is obtained. FIGS. 8 to 9 are sectional view and partial bottom view of a metal mask according to an embodiment of the present invention. As shown in FIGS. 8 to 9, the metal mask 1 comprises a metal body 10, the first opening 210, the second opening 310, and the evaporation hole 600. In the embodiment of FIGS. 8 to 9, a shape of the evaporation hole 600 is the same as that of the first opening 310, which is a rectangular, but it is not limited to this. In some embodiments of the present invention, the shape of the evaporation hole 600 can be different from that of the first opening 310. Taking FIG. 10 as an example, the evaporation hole 600′ has a long octagon, and the shape of the first opening 230′ is similar to but different from the long octagon.

Each of the evaporation holes 600 can have a fourth area S4, and the fourth area S4 is smaller than the third area S3. In the embodiment of the present invention, the metal mask 1 can face an evaporation source with the first surface 200 which serves as an evaporation surface, and each evaporation hole 600 forms an evaporation angle θ relative to the first opening 230. The evaporation angle θ can be an included angle formed between a connecting line and the first surface 200, wherein the connecting line connects a hole edge of the evaporation hole 600 and the edge of the first opening 230. Generally speaking, the value of the evaporation angle θ is one of the design objectives of the metal mask 1, and the evaporation angle θ of the metal mask 1 manufactured by the embodiment of the present invention can better meet the design objective. That is, the manufacturing method of the present invention is beneficial to improving a deviation between a finished product and the design.

The aforementioned design objectives regarding the evaporation angle θ also includes uniformity of the evaporation angle θ on each evaporation hole 600. For example, even though such as a first evaporation angle θ1 and a second evaporation angle θ2 are measured due to different reference points at the evaporation hole 600, the evaporation angle θ1 and the evaporation angle θ2 meet the design objective and are of high uniformity. As illustrated in FIG. 9, the evaporation hole 600 has a first hole edge 611 corresponding to the first edge 251 of the first opening 230, and an included angle formed between a connecting line and the first surface 200 is the first evaporation angle θ1, wherein the connecting line connects a midpoint of the first hole edge 611 and a midpoint of the first edge 251. The evaporation hole 600 also has a second hole edge 612 corresponding to the second edge 252 of the first opening 230, and the second hole edge 612 is adjacent to the first hole edge 611 and together forms a first intersection 630. An included angle formed between a connecting line and the first surface 200 is the second evaporation angle θ2, wherein the connecting line connects the intersection 630 and one of the two adjacent edges (i.e. 251 or 252). In the example of FIG. 9, the second evaporation angle θ2 is formed between the connecting line and the first surface 200, and the connecting line connects the first intersection 630 and the first edge 251, and a projection of the connecting line on the first opening 230 is perpendicular to the first edge 251. In addition, the evaporation angle θ can also be measured from other hole edges of the evaporation hole 600. In the embodiment of the present invention, a difference between the first evaporation angle θ1 and the second evaporation angle θ2 is less than 5 degrees. In sum, since compensation has been made in the embodiment of the present invention for the deviation of the first opening 230 from the design target when preparing the metal mask 1, the evaporation angle θ can better meet the design objective. FIG. 10 illustrates references for measuring the evaporation angle θ of other embodiments such as the evaporation hole 600′.

FIG. 11 is a partial image schematic diagram of a finished metal mask on the evaporation surface according to an embodiment of the present invention. In an embodiment of the present invention, the evaporation hole 600 and the first opening 230 are preset as rectangles. Preferably, as shown in FIG. 11, based on steps S910-S950 and the inwardly concaved curve design of the first aperture 410, the error of the first opening 230 relative to the preset opening region 2000 is small, so that the design target of rectangles can be met. Further, based on steps S910-S950 and the inwardly concaved curve design of the first aperture 410, as shown in FIG. 11, the evaporation angles θ of the evaporation holes 600 are of high uniformity. For example, the first evaporation angle θ1 of the evaporation hole 600 is such as 50.5 degrees, and other evaporation angles such as θ3 and θ4 on the hole edge can be measured as, for example, 49.0 degrees and 48.5 degrees. The difference between θ3 or θ4 and θ1 is less than 5 degrees, so that the design objective of uniformity of the evaporation angles θ is achieved.

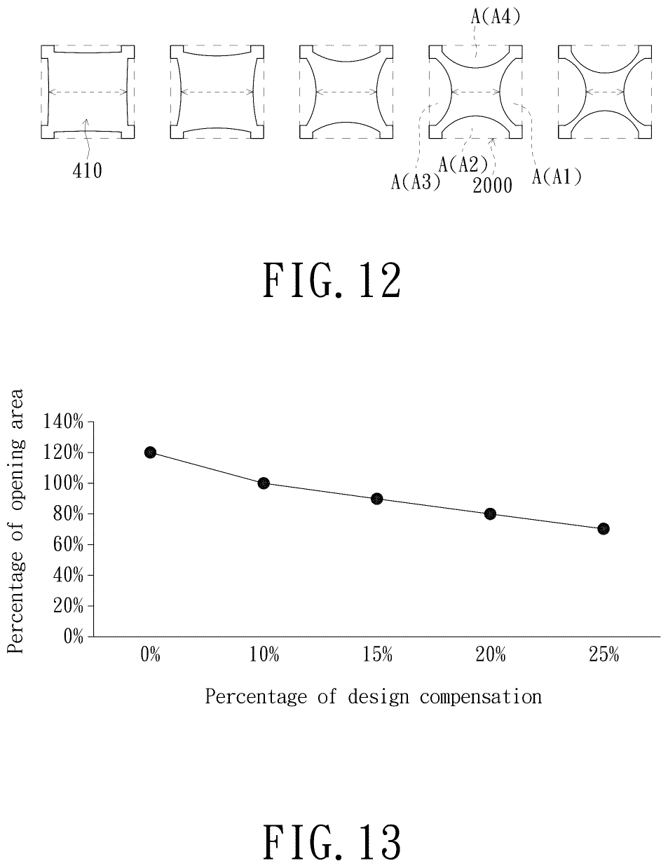

As mentioned above, the regions A are formed between the curves and the preset opening regions 2000. The regions A can also be regarded as design compensation. FIG. 12 illustrates design compensation in different embodiments of the present invention, in which design compensation is increasing from left to right. As mentioned above, the total area of the regions A accounts for 0%-25% of the area (first area S1) of the preset opening region 2000. The percentage is also called a percentage of design compensation. FIG. 13 illustrates a relationship between the percentage of design compensation and the first opening 230 of the metal mask 1 according to different embodiments of the present invention. As shown in FIG. 13, the more the percentage of design compensation, the lower a percentage of an actual area (third area S3) of the first opening 230 relative to the preset opening region 2000. For example, when the percentage of design compensation is zero, the percentage of the third area S3 relative to the first area S1 is much greater than 100%, which means that the first opening 230 is larger than the preset opening region 2000 and deviates from the design target. When the percentage of design compensation is increased, the percentage of the third area S3 relative to the first area S1 can be lowered to nearly 100%, that is, the error between the first opening 230 and the preset opening region 2000 is within an allowable range, and the design objective is met. In the embodiment of the present invention, the area (third area S3) of the first opening 230 obtained by the percentage of design compensation of 0%-25% can be within the allowable range, and the design objective of uniformity of the evaporation angles θ is achieved.

The present invention also provides a metal mask. Referring to FIGS. 8 to 9, in an embodiment of the present invention, the metal mask 1 comprises the metal body 10, the first etching part 210, the second etching part 310, and the evaporation hole 600. The metal body 10 has the first surface 200 and the second surface 300, the first etching part 210 has the first opening 230 located on the first surface 200, the second etching part 310 has the second opening 330 located on the second surface 300, and the second opening 330 is smaller than the first opening 230. The evaporation hole 600 is located between the first etching part 210 and the second etching part 230, and the first etching part 210 and the second etching part 310 are communicated with each other at the evaporation hole 600, wherein the evaporation angle θ formed by the evaporation hole 600 relative to the first opening 230 includes the first evaporation angle θ1 and the second evaporation angle θ2, and a difference between the first evaporation angle θ1 and the second evaporation angle θ2 is less than 5 degrees. The metal mask 1 is preferably prepared by the aforementioned manufacturing method. The metal mask 1 of the embodiment of the present invention can be prepared by steps S910-S950, wherein the area of the first opening 230 can be smaller than that of the preset opening region 2000 to compensate for the deviation caused by the flow of the etching liquid, so that the error of the first opening 230 relative to the preset opening region 2000 is smaller or zero, and the design objectives of the first opening 230 and its evaporation angle θ are achieved. Therefore, the plurality of first openings 230 have higher uniformity in shape, and the value of the evaporation angle θ can meet an expected range.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A manufacturing method of a metal mask, comprising:
providing a metal plate having a first surface and a second surface opposite to each other, wherein the first surface has a plurality of preset opening regions, and each of the preset opening regions has a first area;
forming a first photoresist layer on the first surface of the metal plate, wherein the first photoresist layer has a plurality of first apertures, and each of the first apertures has a second area; the first apertures correspond to the preset opening regions respectively, and each of the preset opening regions is partially exposed to each of the first apertures, wherein the second area is 75%-100% of the first area;
forming a second photoresist layer on the second surface of the metal plate, wherein the second photoresist layer has a plurality of second apertures, and the second surface is exposed to the second apertures;
forming a plurality of first etching parts on the first surface, wherein the first etching parts correspond to the first apertures respectively; each of the first etching parts has a first opening, and each of the first openings is located in each of the preset opening regions; and
forming a plurality of second etching parts on the second surface, wherein the second etching parts correspond to the second apertures respectively.

2. The manufacturing method of the metal mask according to claim 1, further comprising: performing a first etching and a second etching; wherein the first etching comprises forming the first etching parts on the first surface and forming the second etching parts on the second surface; the second etching comprises:
forming a protective layer on the metal plate, wherein the protective layer covers the second photoresist layer and fills the second etching parts; and
performing further etching on the first etching parts, and allowing each of the first etching parts to be communicated with each of the second etching parts to form a plurality of evaporation holes.

3. The manufacturing method of the metal mask according to claim 2, further comprising: removing the first photoresist layer, the second photoresist layer, and the protective layer.

4. The manufacturing method of the metal mask according to claim 2, wherein each of the evaporation holes has a third area, the third area is smaller than the second area, and each of the evaporation holes forms an evaporation angle relative to each of the first openings.

5. The manufacturing method of the metal mask according to claim 4, wherein the evaporation angle is an included angle formed between a connecting line and the first surface; the connecting line connects a hole edge of each of the evaporation holes and an edge of the first opening.

6. The manufacturing method of the metal mask according to claim 5, wherein each of the evaporation holes further has a first hole edge, and each of the first openings further has a first edge corresponding to the first hole edge; the evaporation angle further includes a first evaporation angle, and the first evaporation angle is formed between a connecting line and the first surface; the connecting line connects a midpoint of each of the first hole edges and a midpoint of each of the first edges.

7. The manufacturing method of the metal mask according to claim 6, wherein each of the evaporation holes further has a second hole edge, and each of the second hole edges is adjacent to each of the first hole edges and forms a first intersection; the evaporation angle further includes a second evaporation angle, and the second evaporation angle is formed between a connecting line and the first surface; the connecting line connects the first intersection and the first edge.

8. The manufacturing method of the metal mask according to claim 7, wherein a difference between the first evaporation angle and the second evaporation angle is less than 5 degrees.

9. The manufacturing method of the metal mask according to claim 1, wherein each of the first apertures further has a first side; the step of forming the first photoresist layer further comprises forming the first apertures, and the first side of each of the first apertures has a curve design.

10. The manufacturing method of the metal mask according to claim 9, wherein the first side has an arc curve inwardly concaved towards each of the first apertures.

11. The manufacturing method of the metal mask according to claim 9, wherein each of the first openings further has a first edge corresponding to the first side, and the step of forming the first etching parts further comprises allowing a photoresist of the first photoresist layer to extend out of the first edge and cover a portion of the first etching part.

12. The manufacturing method of the metal mask according to claim 1, wherein each of the first openings is a geometric figure and has a plurality of edges, each of the first apertures has a plurality of sides, and the sides correspond to the edges respectively; the step of forming the first photoresist layer further comprises forming the first apertures, and the sides of each of the first apertures respectively have a curve design.

13. A metal mask comprising:
a metal body having a first surface and a second surface;
a first etching part having a first opening located on the first surface;
a second etching part having a second opening located on the second surface, wherein the second opening is smaller than the first opening; and
an evaporation hole located between the first etching part and the second etching part, wherein the first etching part and the second etching part are communicated with each other at the evaporation hole;
wherein the evaporation hole forms a first evaporation angle and a second evaporation angle relative to the first opening, and a difference between the first evaporation angle and the second evaporation angle is less than 5 degrees.

14. The metal mask according to claim 13, wherein the first evaporation angle is an included angle formed between a connecting line and the first surface, and the connecting line connects a hole edge of the evaporation hole and an edge of the first opening; the second evaporation angle is an included angle formed between a connecting line and the first surface, and the connecting line connects the hole edge of the evaporation hole and an edge of the second opening.

15. The metal mask according to claim 14, wherein the evaporation hole further has a first hole edge, the first opening further has a first edge corresponding to the first hole edge, and the first evaporation angle is formed between a connecting line and the first surface; the connecting line connects a midpoint of the first hole edge and a midpoint of the first edge.

16. The metal mask according to claim 15, wherein the evaporation hole further has a second hole edge, the second hole edge is adjacent to the first hole edge and forms a first intersection, and the second evaporation angle is formed between a connecting line and the first surface; the connecting line connects the first intersection and the first edge.

17. A metal mask prepared by the manufacturing method of the metal mask according to any of claims 1-12.
